(19) United States
(12) Patent Application Publication
(10) Pub. No.: US 2026/0157077 A1
(43) Pub. Date: Jun. 4, 2026

(54) Display Apparatus

(71) Applicant: LG Display Co., Ltd., Seoul (KR)

(72) Inventor: Hyeongjun Lim, Paju-si (KR)

(21) Appl. No.: 19/179,501

(22) Filed: Apr. 15, 2025

(30) Foreign Application Priority Data
Oct. 10, 2024 (KR) 10-2024-0137740

(51) Int. Cl. H10K 59/80; H10K 59/00; H10K 59/12; H10K 59/121; H10K 59/124; H10K 59/88; H10K 102/00

(52) U.S. Cl. CPC H10K 59/80516; H10K 59/1201; H10K 59/121; H10K 59/124; H10K 59/771; H10K 59/80515; H10K 59/80518; H10K 59/88; H10K 2102/341

(57) ABSTRACT

A display apparatus includes a substrate having a first sub-pixel, a second sub-pixel, and a third sub-pixel, each of which includes a light-emitting area and a non-light-emitting area, a first insulating layer disposed on the substrate, a first conductive layer disposed on the first insulating layer and including a first reflective electrode of the first sub-pixel, a first dummy electrode of the second sub-pixel, and a second dummy electrode of the third sub-pixel, a second insulating layer disposed on the first conductive layer, a second conductive layer disposed on the second insulating layer and including a second reflective electrode of the second sub-pixel and a third dummy electrode of the third sub-pixel, a third insulating layer disposed on the second conductive layer, and a third reflective electrode of the third sub-pixel disposed on the third insulating layer.

### CROSS REFERENCE TO RELATED APPLICATION

The present application claims priority to Republic of Korea Patent Application No. 10-2024-0137740, filed on Oct. 10, 2024, which is hereby incorporated by reference in its entirety.

### BACKGROUND

### Field of Technology

The present specification relates to a display apparatus.

### Description of the Related Art

As the information society develops, various demands for display apparatuses for displaying images are increasing, and various types of display apparatuses, such as a liquid crystal display (LCD) apparatus and an organic light emitting diode (OLED) display apparatus, are being utilized.

Among the display apparatuses, there is an advantage in that the OLED display apparatus as the self-luminous type has a wider viewing angle, a higher contrast ratio, can be lighter and thinner, and has lower power consumption than the LCD apparatus because it does not require a separate backlight. In addition, there is an advantage in that the OLED display apparatus can drive at a low voltage, have a fast response time, and especially have the inexpensive manufacturing cost.

Recently, demand for a display apparatus that requires augmented reality (AR), virtual reality (VR), or equivalent ultra-high resolution using such an OLED display apparatus is increasing.

### SUMMARY

The present specification is directed to providing a display apparatus in which it is possible to minimize or at least reduce a thickness deviation of an insulation layer.

The present specification is also directed to providing a display apparatus in which it is possible to minimize or at least reduce a deviation of a microcavity.

The present specification is also directed to providing a display apparatus in which it is possible to enable high color reproduction by emitting more clear color and suppress or prevent image quality from being degraded.

Objects of the present specification are not limited to the above-described objects, and other technical objects may be inferred from the following embodiments.

According to one embodiment of the present specification, there is provided a display apparatus including a substrate having a first sub-pixel, a second sub-pixel, and a third sub-pixel, each of which includes a light-emitting area and a non-light-emitting area, a first insulating layer disposed on the substrate, a first conductive layer disposed on the first insulating layer and including a first reflective electrode of the first sub-pixel, a first dummy electrode of the second sub-pixel, and a second dummy electrode of the third sub-pixel, a second insulating layer disposed on the first conductive layer, a second conductive layer disposed on the second insulating layer and including a second reflective electrode of the second sub-pixel and a third dummy electrode of the third sub-pixel, a third insulating layer disposed on the second conductive layer, and a third reflective electrode of the third sub-pixel disposed on the third insulating layer.

According to another embodiment of the present specification, there is provided a display apparatus including a substrate having a first sub-pixel, a second sub-pixel, and a third sub-pixel, each of which includes a light-emitting area and a non-light-emitting area, a first insulating layer on the substrate, a first reflective electrode of the first sub-pixel on the first insulating layer, a second insulating layer on the first reflective electrode, a second reflective electrode of the second sub-pixel on the second insulating layer, a third insulating layer on the second reflective electrode, a third reflective electrode of the third sub-pixel on the third insulating layer, and anode electrodes of the sub-pixels on the second insulating layer or the third insulating layer, wherein, in the light-emitting area, surface heights of the anode electrodes of the sub-pixels are different.

Detailed matters of other embodiments are included in the detailed description and accompanying drawings.

According to the embodiments of the present specification, it is possible to minimize or at least reduce a thickness deviation of the insulating layer.

According to the embodiments of the present specification, it is possible to minimize or at least reduce a deviation of a microcavity.

According to the embodiments of the present specification, it is possible to enable high-color reproduction by emitting more clear colors and suppress or prevent image quality from being degraded.

According to the embodiments of the present specification, it is possible to enable high-color reproduction and reduce power consumption.

However, effects obtainable from the present specification are not limited to the above-described effects, and other effects that are not mentioned will be able to be clearly understood by those skilled in the art to which the present specification pertains based on the following description.

### BRIEF DESCRIPTION OF THE DRAWINGS

FIG. 1 is a plan view of a display apparatus according to one embodiment.

FIG. 2 is a cross-sectional view along line A-A′ in FIG. 1 according to one embodiment.

FIG. 3 is an enlarged view of area Q1 in FIG. 2 according to one embodiment.

FIG. 4 is a cross-sectional view of an organic light-emitting diode according to FIG. 2 according to one embodiment.

FIG. 5 is a cross-sectional view of an organic light-emitting diode according to a modified example of FIG. 2 according to one embodiment.

FIGS. 6 to 15 are cross-sectional views for each process of a method of manufacturing a display apparatus according to one embodiment.

FIG. 16 is a cross-sectional view of a display apparatus according to another embodiment.

FIG. 17 is an enlarged view of area Q2 in FIG. 16 according to one embodiment.

FIG. 18 is a cross-sectional view of a display apparatus according to still another embodiment.

FIG. 19 is a cross-sectional view of a display apparatus according to yet another embodiment.

### DETAILED DESCRIPTION

Hereinafter, embodiments will be described with reference to the accompanying drawings. In the specification, when a first component (or an area, a layer, a portion, or the like) is described as “on,” “connected,” or “coupled to” a second component, it means that the first component may be directly connected/coupled to the second component or a third component may be disposed therebetween.

The same reference numerals indicate the same components. In addition, in the drawings, thicknesses, proportions, and dimensions of components are exaggerated for effective description of technical contents. The term “and/or” includes all one or more combinations that may be defined by the associated configurations.

Terms such as first and second may be used to describe various components, but the components are not limited by the terms. The terms are used only for the purpose of distinguishing one component from another. For example, a first component may be referred to as a second component, and similarly, the second component may also be referred to as the first component without departing from the scopes of the embodiments. The singular includes the plural unless the context clearly dictates otherwise.

Terms such as “under,” “at a lower side,” “above,” and “at an upper side” are used to describe the relationship between the components illustrated in the drawings. The terms are relative concepts and are described with respect to directions marked in the drawings.

It should be understood that term such as “includes” or “has” is intended to specify the presence of features, numbers, steps, operations, components, parts, or a combination thereof described in the specification and does not preclude the presence or addition possibility of one or more other features, numbers, steps, operations, components, parts, or combinations thereof in advance.

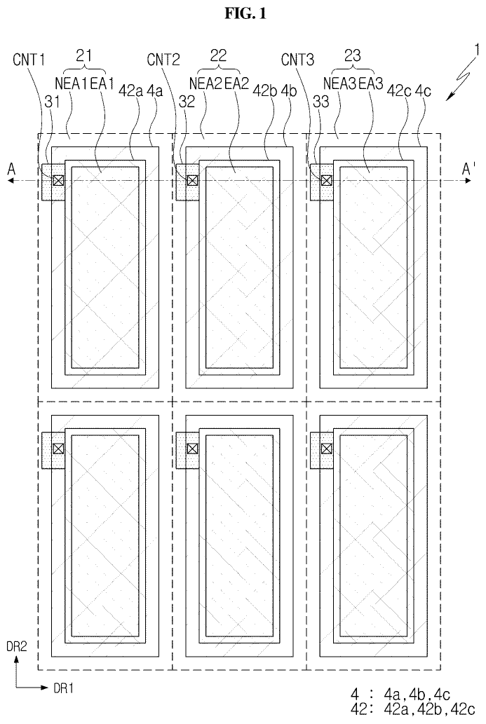

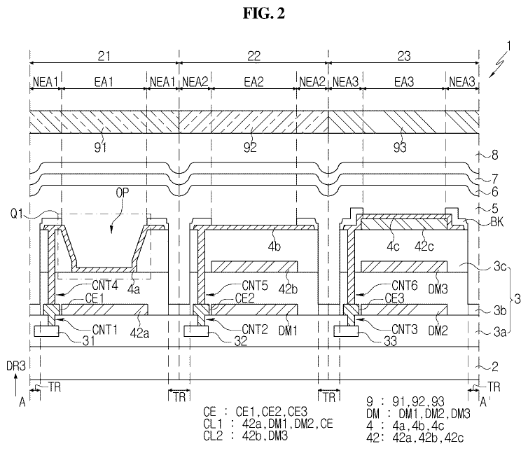

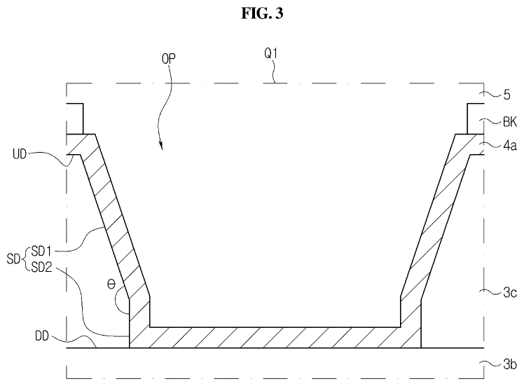

FIG. 1 is a plan view of a display apparatus according to one embodiment. FIG. 2 is a cross-sectional view along line A-A′ in FIG. 1. FIG. 3 is an enlarged view of area Q1 in FIG. 2.

Referring to FIGS. 1 to 3, a display apparatus 1 according to one embodiment includes a substrate 2, reflective electrodes 42a, 42b, and 42c, a dummy electrode DM (DM1, DM2, and DM3), an anode electrode 4 (4a, 4b, and 4c), a common light-emitting layer 5, and a cathode electrode 6.

A plurality of sub-pixels 21, 22, and 23 are formed on the substrate 2. The plurality of sub-pixels 21, 22, and 23 may form one pixel. The plurality of pixels may be formed on the substrate 2.

The plurality of sub-pixels 21, 22, and 23 include a first sub-pixel 21, a second sub-pixel 22, and a third sub-pixel 23. The first sub-pixel 21, the second sub-pixel 22, and the third sub-pixel 23 may be disposed sequentially, alternately, and repeatedly in a first direction DR1. Each of the first sub-pixel 21, the second sub-pixel 22, and the third sub-pixel 23 may be disposed repeatedly in a second direction DR2.

Since the first sub-pixel 21, the second sub-pixel 22, and the third sub-pixel 23 may be arranged sequentially, the second sub-pixel 22 may be disposed adjacent to one side, for example, the right side of the first sub-pixel 21, and the third sub-pixel 23 may be disposed adjacent to one side, for example, the right side of the second sub-pixel 22.

Throughout the present specification, when two sub-pixels are disposed adjacent to each other, it may be construed to mean that no other sub-pixels are disposed between the two sub-pixels.

The first sub-pixel 21 may be provided to emit red (R) light, the second sub-pixel 22 may be provided to emit green (G) light, and the third sub-pixel 23 may be provided to emit blue (B) light, but the embodiments of the present specification are not necessarily limited thereto.

FIG. 1 illustrates an example in which a pixel includes only three sub-pixels 21, 22, and 23, but the embodiments of the present specification are not limited thereto, and the pixel may include four sub-pixels. When the pixel includes four sub-pixels, the pixel may further include a fourth sub-pixel provided to emit white (W) light.

Each of the first to third sub-pixels 21, 22, and 23 may be provided to have the same size. For example, each of the first to third sub-pixels 21, 22, and 23 may be provided to have the same width and the same height.

Here, the width may refer to a horizontal direction (the first direction DR1) based on FIG. 1, and the height may refer to a direction (the second direction DR2) perpendicular to the width based on FIG. 1, but the embodiments of the present specification are not necessarily limited thereto. The first direction DR1 may intersect the second direction DR2, and a third direction DR3 may intersect the first direction DR1 and the second direction DR2. The third direction DR3 may refer to a thickness direction of the display apparatus 1, but is not limited thereto.

The first direction DR1, the second direction DR2, and the third direction DR3 may be understood as relative directions and are not limited to embodiments of the present specification.

FIG. 1 illustrates each sub-pixel 21, 22, or 23 having a height in the second direction DR2 that is greater than a width in the first direction DR1 and a stripe type in which the sub-pixels 21, 22, and 23 are disposed sequentially and repeatedly in the first direction DR1, but the flat surface shapes and arrangement of the sub-pixels 21, 22, and 23 are not limited thereto and may be diverse.

For example, two sub-pixels selected from the sub-pixels 21, 22, and 23 may be disposed adjacent to each other in the first direction DR1, and the remaining one may be disposed at one or the other side of the two sub-pixels in the second direction DR2. In this case, the two sub-pixels may extend in the second direction DR2, and the remaining one may extend in the first direction DR1, but the embodiments of the present specification are not limited thereto.

That is, each sub-pixel 21, 22, or 23 may be disposed in at least one selected from, for example, a stripe type, a planar S-stripe type, a pentile type, a diamond structure type, etc.

A bank BK may be disposed in each of the first sub-pixel 21, the second sub-pixel 22, and the third sub-pixel 23. The bank BK may define light-emitting areas EA1, EA2, and EA3 of the sub-pixels 21, 22, and 23.

The bank BK is illustrated as being formed of a single layer, but is not limited thereto, and the bank BK may be formed of multiple layers. The bank BK may be formed of an inorganic insulation material, but is not limited thereto.

The sub-pixels 21, 22, and 23 may include the light-emitting areas EA1, EA2, and EA3 and non-light-emitting areas NEA1, NEA2, and NEA3, respectively. A first sub-pixel 21 may include a first light-emitting area EA1 and a first non-light-emitting area NEA1 around the first light-emitting area EA1. A second sub-pixel 22 may include a second light-emitting area EA2 and a second non-light-emitting area NEA2 around the second light-emitting area EA2. The third sub-pixel 23 may include a third light-emitting area EA3 and a third non-light-emitting area NEA3 around the third light-emitting area EA3. Each light-emitting area EA1, EA2, or EA3 may be the same as an area exposed from the bank BK of the anode electrode 4a, 4b, or 4c to be described below.

The anode electrode 4 is patterned for each sub-pixel 21, 22, or 23. That is, one anode electrode 4 is formed in the first sub-pixel 21, another anode electrode 4 is formed in the second sub-pixel 22, and still another anode electrode 4 is formed in the third sub-pixel 23.

The anode electrode 4 may include a first anode electrode 4a, a second anode electrode 4b, and a third anode electrode 4c. The first anode electrode 4a, the second anode electrode 4b, and the third anode electrode 4c may be disposed in the sub-pixel 21, 22, and 23, respectively.

The anode electrode 4 may serve as an anode of the display apparatus 1. The bank BK may be provided to cover an edge of the anode electrode 4 disposed in each of the first to third sub-pixels 21, 22, and 23 to distinguish the first sub-pixel 21, the second sub-pixel 22, and the third sub-pixel 23.

The display apparatus 1 may have the reflective electrodes 42 with different surface heights, thereby further increasing light extraction efficiency using the microcavity characteristic.

The microcavity characteristic refers to a characteristic that, when a distance between the reflective electrode 42 and the cathode electrode 6 is an integer multiple of a half wavelength (λ/2) of light emitted from a sub-pixel, constructive interference occurs to amplify the light, and when a reflection and re-reflection process is repeated between the reflective electrode 42 and the cathode electrode 6, a degree of light being amplified continuously increases, thereby increasing the external extraction efficiency of light.

The common light-emitting layer 5 may be provided to emit white light. For example, the common light-emitting layer 5 may be provided to emit white light by having a two-stack structure including a blue light-emitting layer, a yellow-green light-emitting layer, and a charge generation layer or a three-stack structure including a blue light-emitting layer, a green light-emitting layer, a red light-emitting layer, and a charge generation layer, but is not necessarily limited thereto, and may be formed of multiple layers exceeding 3 stacks as long as it may emit white light.

The common light-emitting layer 5 may be formed as a common layer across the first to third sub-pixels 21, 22, and 23.

The cathode electrode 6 is used to generate an electric field with the anode electrode 4 and may serve as a cathode. The cathode electrode 6 may be disposed on an upper surface of the common light-emitting layer 5, which is opposite to a lower surface of the common light-emitting layer 5 that comes into contact with the anode electrode 4 and provided as a common layer throughout the first to third sub-pixels 21, 22, and 23.

In the case of a top emission type, the cathode electrode 6 may be provided as a first electrode, and in the case of a bottom emission type, the cathode electrode 6 may be provided as an opaque cathode electrode including a reflective material. In the case of the top emission type, the cathode electrode 6 may be formed as a cathode electrode including a translucent material to increase light extraction efficiency using the microcavity characteristic. Since the display apparatus 1 increases light extraction efficiency using the microcavity characteristic in the top emission type, an example in which the cathode electrode 6 is formed as a cathode electrode including a translucent material will be described.

A color filter layer 9 is provided in each of the first to third sub-pixels 21, 22, and 23 to block a specific color from light emitted from the light-emitting layer of each sub-pixel. The color filter layer 9 may include a first color filter 91 provided in the first sub-pixel 21, a second color filter 92 provided in the second sub-pixel 22, and a third color filter 93 provided in the third sub-pixel 23.

The first color filter 91 may be provided to block light of other colors not including red (R) light. In this case, the first color filter 91 may be provided as a red color filter. The second color filter 92 may be provided to block light of other colors not including green (G) light. In this case, the second color filter 92 may be provided as a green color filter. The third color filter 93 may be provided to block light of other colors not including blue (B) light. In this case, the third color filter 93 may be provided as a blue color filter. However, the embodiments of the present specification are not necessarily limited thereto.

The first to third color filters 91, 92, and 93 provided in the first to third sub-pixels 21, 22, and 23, respectively, may be provided in the same size as the respective sub-pixels or provided by being reduced or expanded at a predetermined ratio to each sub-pixel.

The transistors 31, 32, and 33 may be disposed in the non-light-emitting areas NEA1, NEA2, and NEA3 of the sub-pixels 21, 22, and 23, respectively. For example, the transistors 31, 32, and 33 may be located at one sides of reflective electrodes 42a, 42b, and 42c in the first direction DR1, but are not limited thereto. For example, at least parts of the transistors 31, 32, and 33 may be disposed in the light-emitting areas EA1, EA2, and EA3 and disposed under the reflective electrodes 42a, 42b, and 42c, and in this case, the transistors 31, 32, and 33 cannot be visible from the outside.

The anode electrodes 4a, 4b, and 4c and the transistors 31, 32, and 33 that are disposed in the sub-pixels 21, 22, and 23, respectively, may correspond to each other. The anode electrodes 4a, 4b, and 4c may be electrically connected to the corresponding transistors 31, 32, and 33, respectively, through first to sixth contact holes CNT1, CNT2, CNT3, CNT4, CNT5, and CNT6 and a connection electrode CE (CE1, CE2, and CE3) that are disposed in the sub-pixel 21, 22, and 23.

The transistors 31, 32, and 33 may include first to third transistors 31, 32, and 33 corresponding to the first to third sub-pixels 21, 22, and 23, respectively.

The connection electrode CE may include a first connection electrode CE1, a second connection electrode CE2, and a third connection electrode CE3 disposed in the sub-pixels 21, 22, and 23, respectively. The connection electrode CE may include the same material as a first reflective electrode 42a, but is not limited thereto, and may be formed of a different material.

The first connection electrode CE1 may be electrically connected in contact with the first transistor 31 through a first contact hole CNT1. The second connection electrode CE2 may be electrically connected in contact with the second transistor 32 through a second contact hole CNT2. The third connection electrode CE3 may be electrically connected in contact with the third transistor 33 through a third contact hole CNT3.

The first anode electrode 4a may be electrically connected in contact with the first connection electrode CE1 through a fourth contact hole CNT4. The second anode electrode 4b may be electrically connected in contact with the second connection electrode CE2 through a fifth contact hole CNT5. The third anode electrode 4c may be electrically connected in contact with the third connection electrode CE3 through a sixth contact hole CNT6.

In the light-emitting areas EA1, EA2, and EA3, surface heights of the anode electrodes 4a, 4b, and 4c disposed in the sub-pixels 21, 22, and 23, respectively, may be different. A surface height of the third anode electrode 4c disposed in the third light-emitting area EA3 of the third sub-pixel 23 may be greater than a surface height of the second anode electrode 4b disposed in the second light-emitting area EA2 of the second sub-pixel 22. The surface height of the second anode electrode 4b disposed in the second light-emitting area EA2 of the second sub-pixel 22 may be greater than a surface height of the first anode electrode 4a disposed in the first light-emitting area EA1 of the first sub-pixel 21.

The anode electrodes 4a, 4b, and 4c disposed in the sub-pixels 21, 22, and 23, respectively, may be disposed on different layers in the light-emitting areas EA1, EA2, and EA3. In the first light-emitting area EA1, the first anode electrode 4a may be disposed on a second insulating layer 3b and may come into direct contact with the second insulating layer 3b. In the second light-emitting area EA2, the second anode electrode 4b may be disposed on a third insulating layer 3c and may come into direct contact with the third insulating layer 3c. In the third light-emitting area EA3, the third anode electrode 4c may be disposed on a third reflective electrode 42c and may come into direct contact with the third reflective electrode 42c.

A trench TR may be disposed between the sub-pixels 21, 22, and 23 (or between the light-emitting areas EA1, EA2, and EA3 of the sub-pixels 21, 22, and 23. In a plan view, the trench TR may extend between the sub-pixels 21, 22, and 23 in the first direction DR1 and the second direction DR2.

The trench TR may be defined by a second insulating layer 3b and a third insulating layer 3c. The trench TR may be formed in a groove or recess shape by removing at least parts of the second insulating layer 3b and the third insulating layer 3c.

The trench TR may be formed in a shape which passes through the third insulating layer 3c in the thickness direction (the third direction DR3) and in which a part of the second insulating layer 3b is removed. That is, the trench TR may be defined by a side surface of the third insulating layer 3c and a side surface and upper surface of the second insulating layer 3b, but is not limited thereto. For example, the trench TR may pass through the third insulating layer 3c and the second insulating layer 3b in the thickness direction (the third direction DR3) to expose the first insulating layer 3a.

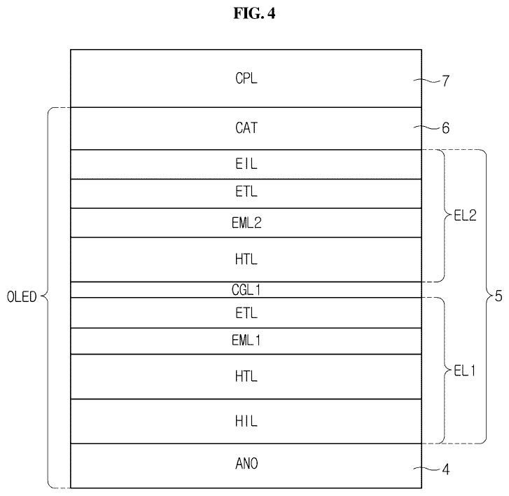

As the trench TR is disposed between the sub-pixels 21, 22, and 23, even when the common light-emitting layer 5 and the cathode electrode 6 are disposed across the sub-pixels 21, 22, and 23, a first stack EL1 (see FIG. 4) and a first charge generation layer CGL1 (see FIG. 4) are separated in each sub-pixel 21, 22, or 23, and a second stack EL2 (see FIG. 4) may be disposed between the first charge generation layer CGL1 (see FIG. 4) and the cathode electrode 6.

Accordingly, it is possible to prevent or at least reduce a leakage current between the adjacent sub-pixels 21, 22, and 23, prevent or at least reduce a likelihood of a short circuit between the charge generation layer CGL1 and the cathode electrode 6, and prevent light color mixing.

Hereinafter, the stacking structure of the display apparatus 1 according to one embodiment will be described in detail.

The display apparatus 1 according to one embodiment includes the substrate 2, the insulating layer 3, the connection electrode CE, the dummy electrode DM, the anode electrode 4, the bank BK, the common light-emitting layer 5, the cathode electrode 6, a capping layer 7, an encapsulation layer 8, and the color filter layer 9.

The substrate 2 may be a plastic film, a glass substrate, or a semiconductor substrate, such as silicon.

The substrate 2 may be formed of a transparent material or an opaque material. The first sub-pixel 21, the second sub-pixel 22, and the third sub-pixel 23 are provided on the substrate 2. The first sub-pixel 21 may be provided to emit red (R) light, the second sub-pixel 22 may be provided to emit green (G) light, and the third sub-pixel 23 may be provided to emit blue (B) light.

Since the display apparatus 1 according to one embodiment is configured in a so-called top emission type in which emitted light is emitted upward, both a transparent material and an opaque material may be used as a material of the substrate 2. The color filters 91, 92, and 93 may be respectively provided above the first to third sub-pixels 21, 22, and 23 from which light is emitted to transmit light of the above colors.

The insulating layer 3 is formed on the substrate 2. The insulating layer 3 may include a plurality of insulating layers 3a, 3b, and 3c. Hereinafter, the insulating layer 3 is described as including the first to third insulating layers 3a, 3b, and 3c, but is not limited thereto, and an additional insulating layer may be further disposed between the first to third insulating layers 3a, 3b, and 3c.

The first insulating layer 3a is disposed on the substrate 2, and circuit elements including the plurality of thin film transistors 31, 32, and 33, various signal lines, capacitors, etc. are provided in the first insulating layer 3a of each sub-pixel 21, 22, or 23. Each of the plurality of transistors 31, 32, and 33 may be formed as a thin film transistor, but is not limited thereto.

The signal lines may include a gate line, a data line, a power line, and a reference line, and the transistors 31, 32, and 33 may include a switching transistor, a driving transistor, and a sensing transistor. Each of the sub-pixels 21, 22, and 23 is defined by an intersection structure of gate lines and data lines.

The switching transistor is switched according to a gate signal supplied to the gate line to supply a data voltage supplied from the data line to the driving transistor.

The driving transistor is switched according to the data voltage supplied from the switching transistor to generate a data current from a power source supplied from the power line and supply the data current to the anode electrode 4.

The sensing transistor serves to detect a threshold voltage deviation of the driving transistor, which causes the degradation of image quality, and supplies the current of the driving transistor to the reference line in response to a sensing control signal supplied from the gate line or a separate sensing line.

The capacitor serves to maintain the data voltage supplied to the driving transistor for one frame and is connected to each of a gate terminal and a source terminal of the driving transistor.

A first transistor 31, a second transistor 32, and a third transistor 33 are respectively disposed in the sub-pixels 21, 22, and 23 in the first insulating layer 3a. The first transistor 31 may be connected to the first anode electrode 4a disposed on the first sub-pixel 21 to apply a driving voltage for emitting light of a color corresponding to the first sub-pixel 21.

The second transistor 32 may be connected to the second anode electrode 4b disposed on the second sub-pixel 22 to apply a driving voltage for emitting light of a color corresponding to the second sub-pixel 22.

The third transistor 33 may be connected to the third anode electrode 4c disposed on the third sub-pixel 23 to apply a driving voltage for emitting light of a color corresponding to the third sub-pixel 23.

When receiving the gate signal from the gate line using each of the transistors 31, 32, and 33, each of the first sub-pixel 21, the second sub-pixel 22, and the third sub-pixel 23 supplies a predetermined current to the light-emitting layer according to the data voltage of the data line. Accordingly, the light-emitting layer of each of the first sub-pixel 21, the second sub-pixel 22, and the third sub-pixel 23 may emit light with a predetermined brightness according to the predetermined current.

The first insulating layer 3a may protect the transistors 31, 32, and 33. The first insulating layer 3a may be formed of an inorganic insulation material, but is not necessarily limited thereto and may be formed of an organic insulation material. The transistors 31, 32, and 33 may be located in the first insulating layer 3a. For example, the first insulating layer 3a may be formed of an inorganic material, such as silicon nitride (SiNx), silicon oxide (SiOx), aluminum oxide (Al2O3), etc., but the embodiments of the present specification are not limited thereto.

The second insulating layer 3b may be disposed on the first insulating layer 3a. For example, the second insulating layer 3b may be formed of an inorganic material, such as silicon nitride (SiNx), silicon oxide (SiOx), aluminum oxide (Al2O3), etc., but the embodiments of the present specification are not limited thereto.

The third insulating layer 3c may be disposed on the second insulating layer 3b. For example, the third insulating layer 3c may be formed of an inorganic material, such as silicon nitride (SiNx), silicon oxide (SiOx), aluminum oxide (Al2O3), etc., but the embodiments of the present specification are not limited thereto.

However, the embodiments of the present specification are not limited thereto, and an additional insulating layer may be further disposed between the insulating layers 3a, 3b, and 3c.

In the first sub-pixel 21, the first insulating layer 3a, the first transistor 31 disposed in the first insulating layer 3a, the first reflective electrode 42a disposed on the first insulating layer 3a, the second insulating layer 3b disposed on the first reflective electrode 42a, the third insulating layer 3c disposed on the second insulating layer 3b, the first anode electrode 4a disposed on the second insulating layer 3b and the third insulating layer 3c, and the bank BK disposed on the first anode electrode 4a may be disposed sequentially on the substrate 2.

The third insulating layer 3c may define an opening OP exposing the second insulating layer 3b. The opening OP may pass through the third insulating layer 3c in the thickness direction (the third direction DR3) to expose the second insulating layer 3b.

The opening OP may be defined by sidewalls SD formed of the third insulating layer 3c. The sidewall SD of the opening OP may be formed of an exposed side surface of the third insulating layer 3c.

The sidewall SD may include a first sidewall SD1 and a second sidewall SD2 having different slopes. The first sidewall SD1 and the second sidewall SD2 may have different angles with respect to the thickness direction (the third direction DR3). The first sidewall SD1 and the second sidewall SD2 may be formed to have a predetermined angle θ in a cross-sectional view.

The first sidewall SD1 may extend from an upper surface UD of the third insulating layer 3c to form a part of the sidewall SD of the opening OP. The second sidewall SD2 extends from the first sidewall SD1 to form a remaining part of the sidewall SD of the opening OP and may be connected to a lower surface DD of the third insulating layer 3c.

That is, the first sidewall SD1 may be disposed between the upper surface UD of the third insulating layer 3c and the second sidewall SD2. The second sidewall SD2 may be disposed between the first sidewall SD1 and the lower surface DD of the third insulating layer 3c.

The upper surface UD of the third insulating layer 3c may be a surface facing the bank BK, and the lower surface DD of the third insulating layer 3c may refer to a surface facing the second insulating layer 3b.

The first anode electrode 4a may be disposed across the third insulating layer 3c and the second insulating layer 3b. At least a part of the first anode electrode 4a may be disposed in the opening OP. The first anode electrode 4a may be disposed on the upper surface UD of the third insulating layer 3c and the sidewall SD of the opening OP and disposed on the second insulating layer 3b exposed by the opening OP.

In the first light-emitting area EA1, at least a part of the first anode electrode 4a may be disposed on the second insulating layer 3b and may come into direct contact with the second insulating layer 3b. In the first light-emitting area EA1, the first anode electrode 4a may be further disposed on the sidewall SD.

In the first sub-pixel 21, the first reflective electrode 42a may be patterned and disposed across the first light-emitting area EA1 and the first non-light-emitting area NEA1.

The first reflective electrode 42a may be disposed on the first insulating layer 3a. The first reflective electrode 42a may be disposed under the first anode electrode 4a with the second insulating layer 3b interposed therebetween.

In the second sub-pixel 22, the first insulating layer 3a, the second transistor 32 disposed in the first insulating layer 3a, a first dummy electrode DM1 disposed on the first insulating layer 3a, the second insulating layer 3b disposed on the first dummy electrode DM1, the second reflective electrode 42b disposed on the second insulating layer 3b, the third insulating layer 3c disposed on the second reflective electrode 42b, the second anode electrode 4b disposed on the third insulating layer 3c, and the bank BK disposed on the second anode electrode 4b may be disposed sequentially on the substrate 2.

In the second sub-pixel 22, the second reflective electrode 42b may be patterned and disposed across the second light-emitting area EA2 and the second non-light-emitting area NEA2. In the second sub-pixel 22, the first dummy electrode DM1 may be patterned and disposed in the second light-emitting area EA2 and the second non-light-emitting area NEA2.

The first dummy electrode DM1 may include the same metal as the first reflective electrode 42a. The first dummy electrode DM1 may be formed by the same mask process as the first reflective electrode 42a.

The first dummy electrode DM1 may overlap the second reflective electrode 42b in the thickness direction (the third direction DR3).

In the second light-emitting area EA2, the second anode electrode 4b may be disposed on the third insulating layer 3c and may come into direct contact with the third insulating layer 3c.

In the third sub-pixel 23, the first insulating layer 3a, the third transistor 33 disposed in the first insulating layer 3a, a second dummy electrode DM2 disposed on the first insulating layer 3a, the second insulating layer 3b disposed on the second dummy electrode DM2, a third dummy electrode DM3 disposed on the second insulating layer 3b, the third insulating layer 3c disposed on the third dummy electrode DM3, the third reflective electrode 42c disposed on the third insulating layer 3c, the third anode electrode 4c disposed on the third reflective electrode 42c, and the bank BK disposed on the third anode electrode 4c may be disposed sequentially on the substrate 2.

In the third sub-pixel 23, the third reflective electrode 42c may be patterned and disposed across the third light-emitting area EA3 and the third non-light-emitting area NEA3. In the third sub-pixel 23, the second dummy electrode DM2 and the third dummy electrode DM3 may be patterned and disposed in the third light-emitting area EA3 and the third non-light-emitting area NEA3.

The first reflective electrode 42a disposed in the first sub-pixel 21, the first dummy electrode DM1 disposed in the second sub-pixel 22, and the second dummy electrode DM2 disposed in the third sub-pixel 23 may be formed in the same layer, formed of the same material, and formed by the same process. However, the embodiments of the present specification are not limited thereto.

The second dummy electrode DM2 may overlap the third dummy electrode DM3 and the second reflective electrode 42b in the thickness direction (the third direction DR3).

The first reflective electrode 42a disposed in the first sub-pixel 21, the first dummy electrode DM1 disposed in the second sub-pixel 22, the second dummy electrode DM2 disposed in the third sub-pixel 23, and the connection electrode CE may form a first conductive layer CL1. The first conductive layer CL1 may include the first reflective electrode 42a, the first dummy electrode DM1, the second dummy electrode DM2, and the connection electrode CE.

The first reflective electrode 42a disposed in the first sub-pixel 21, the first dummy electrode DM1 disposed in the second sub-pixel 22, and the second dummy electrode DM2 disposed in the third sub-pixel 23 may be disposed separately. However, the embodiments of the present specification are not limited thereto.

The first reflective electrode 42a, the first dummy electrode DM1, and the second dummy electrode DM2 can suppress or prevent the first insulating layer 3a disposed thereunder from being over-etched. Accordingly, it is possible to minimize or at least reduce a thickness deviation of the first insulating layers 3a disposed in the sub-pixels 21, 22, and 23 and a thickness deviation of the first insulating layers 3a in each manufactured display apparatus 1.

Accordingly, it is possible to minimize or at least reduce a deviation of the microcavity of the sub-pixels 21, 22, and 23, and further, in the display apparatus 1, it is possible to enable high-color reproduction by emitting more clear colors, suppress or prevent the degradation of image quality, and reduce power consumption.

The second reflective electrode 42b disposed in the second sub-pixel 22 and the third dummy electrode DM3 disposed in the third sub-pixel 23 may be disposed separately, but may be formed on the same layer, formed of the same material, and formed by the same process, but are not limited thereto.

The second reflective electrode 42b disposed in the second sub-pixel 22 and the third dummy electrode DM3 disposed in the third sub-pixel 23 may form a second conductive layer CL2. The second conductive layer CL2 may include the second reflective electrode 42b and the third dummy electrode DM3.

The second reflective electrode 42b and the third dummy electrode DM3 can suppress or prevent the second insulating layer 3b disposed thereunder from being over-etched. Accordingly, it is possible to minimize the thickness deviation of the second insulating layer 3b.

Accordingly, it is possible to minimize a deviation of the microcavity of the sub-pixels 21, 22, and 23, and further, in the display apparatus 1, it is possible to enable high-color reproduction by emitting more clear colors, suppress or prevent the degradation of image quality, and reduce power consumption.

The first to sixth contact holes CNT1 to CNT6 may be disposed in non-light-emitting areas NEA1, NEA2, and NEA3. Each of the first to sixth contact holes CNT1 to CNT6 may be defined by passing through at least one of the first to third insulating layers 3a to 3c in the thickness direction and may electrically connect the transistors 31, 32, and 33, the connection electrode CE, and the anode electrode 4 (4a, 4b, and 4c) in the sub-pixels 21, 22, and 23.

The first contact hole CNT1 may be defined by the first insulating layer 3a in the first non-light-emitting area NEA1. The first contact hole CNT1 may pass through the first insulating layer 3a in the thickness direction (the third direction DR3) to expose the first transistor 31. In the first non-light-emitting area NEA1, the first connection electrode CE1 may come into contact with the first transistor 31 through the first contact hole CNT1.

The second contact hole CNT2 may be defined by the first insulating layer 3a in the second non-light-emitting area NEA2. The second contact hole CNT2 may pass through the first insulating layer 3a in the thickness direction (the third direction DR3) to expose the second transistor 32. In the second non-light-emitting area NEA2, the second connection electrode CE2 may come into contact with the second transistor 32 through the second contact hole CNT2.

The third contact hole CNT3 may be defined by the first insulating layer 3a in the third non-light-emitting area NEA3. The third contact hole CNT3 may pass through the first insulating layer 3a in the thickness direction (the third direction DR3) to expose the third transistor 33. In the third light-emitting area NEA3, the third connection electrode CE3 may come into contact with the first transistor 31 through the third contact hole CNT3.

The fourth contact hole CNT4 may be defined by the second to third insulating layers 3b to 3c in the first non-light-emitting area NEA1. The fourth contact hole CNT4 may pass through the second to third insulating layers 3b to 3c in the thickness direction (the third direction DR3) to expose the first connection electrode CE1. In the first non-light-emitting area NEA1, the first anode electrode 4a may come into contact with the first connection electrode CE1 through the fourth contact hole CNT4.

The fifth contact hole CNT5 may be defined by the second to third insulating layers 3b to 3c in the second non-light-emitting area NEA2. The fifth contact hole CNT5 may pass through the second to third insulating layers 3b to 3c in the thickness direction (the third direction DR3) to expose the second connection electrode CE2. In the second non-light-emitting area NEA2, the second anode electrode 4b may come into contact with the second connection electrode CE2 through the fifth contact hole CNT5.

The sixth contact hole CNT6 may be defined by the second to third insulating layers 3b to 3c in the third non-light-emitting area NEA3. The sixth contact hole CNT6 may pass through the second to third insulating layers 3b to 3c in the thickness direction (the third direction DR3) to expose the third connection electrode CE3. In the third non-light-emitting area NEA3, the third anode electrode 4c may come into contact with the third connection electrode CE3 through the sixth contact hole CNT6.

The transistors 31, 32, and 33 have been described above as coming into electrical contact with the anode electrodes 4a, 4b, and 4c through the contact holes CNT1, CNT2, CNT3, CNT4, CNT5, and CNT6 and the connection electrode CE, but the embodiments of the present specification are not limited thereto.

For example, the fourth to sixth contact holes CNT4, CNT5, and CNT6 may be filled with a separate contact layer (not illustrated), and the connection electrodes CE1, CE2, and CE3 may be electrically connected to the anode electrodes 4a, 4b, and 4c by the contact layer filling the fourth to sixth contact holes CNT4, CNT5, and CNT6. Here, the contact layer (not illustrated) may be formed of tungsten, etc.

Alternatively, the connection electrode CE may be omitted, and the transistors 31, 32, and 33 may come into direct contact with the anode electrode 4a, 4b, and 4c through one contact hole in the sub-pixels 21, 22, and 23.

The reflective electrode 42 (42a, 42b, and 42c) may reflect light, which is emitted toward the reflective electrode 42 among light emitted from the common light-emitting layer 5 of the sub-pixel 21, 22, and 23, toward the cathode electrode 6 or the encapsulation layer 8. In addition, the reflective electrode 42 is formed to implement the microcavity characteristic through reflection and re-reflection with the cathode electrode 6. To this end, the reflective electrode 42 may include a reflective material for reflecting light. For example, the reflective material may be a metal, but is not necessarily limited thereto, and may be other materials as long as it may reflect light. For example, the reflective material may include titanium (Ti)/aluminum (Al), but is not limited thereto.

The display apparatus 1 according to one embodiment may be provided in the top emission type, and to this end, the reflective electrode 42 may be provided to reflect the light emitted from the common light-emitting layer 5 upward.

The reflective electrode 42 may reflect light, which is emitted toward the reflective electrode 42 among the light emitted from the common light-emitting layer 5 of each sub-pixel 21, 22, or 23, toward the cathode electrode 6 or the encapsulation layer 8. In addition, the reflective electrode 42 is formed to implement the microcavity characteristic through reflection and re-reflection with the cathode electrode 6. To this end, the reflective electrode 42 may include a reflective material for reflecting light.

Since the reflective electrode 42 is disposed at a relatively lower location than the common light-emitting layer 5 for emitting light, the reflective electrode 42 may reflect the light emitted from the common light-emitting layer 5 upward. Here, upward may refer to a direction in which a user may perceive light, for example, a side to which the encapsulation layer 8 or the color filter layer 9 is disposed. Accordingly, it is possible to further increase the light efficiency of the first sub-pixel 21, the second sub-pixel 22, and the third sub-pixel 23 compared to a case in which there is no reflective electrode 42, and the user can perceive an image with high brightness, that is, clear image, through the increased light efficiency. That is, the user can perceive a clear image.

As described above, the display apparatus 1 may have the reflective electrode 42, thereby further increasing light extraction efficiency using the microcavity characteristic. The reflective electrode 42 may include the first reflective electrode 42a, the second reflective electrode 42b, and the third reflective electrode 42c.

A distance between the first reflective electrode 42a and the anode electrode 4 may be larger than a distance between the second reflective electrode 42b and the anode electrode 4. The distance between the second reflective electrode 42b and the anode electrode 4 may be larger than a distance between the third reflective electrode 42c and the anode electrode 4.

The cathode electrode 6 in the light-emitting area EA1, EA2, and EA3 of the sub-pixels 21, 22, and 23 may be located colinearly. Accordingly, a size relationship between the distances between the reflective electrodes 42a, 42b, and 42c and the anode electrode 4 in the sub-pixel 21, 22, and 23 may be the same as a size relationship between the distances between the reflective electrodes 42a, 42b, and 42c and the cathode electrodes 6.

In this way, the reason why the reflective electrodes 42a, 42b, and 42c are formed to have various separation distances (or resonance distances) from the cathode electrode 6 is that the light extraction efficiency of different colors can be increased through reflection and re-reflection between the reflective electrodes 42a, 42b, and 42c and the cathode electrode 6 according to the separation distances. Accordingly, it is possible to increase the light extraction efficiency of red light in the first sub-pixel 21, increase the light extraction efficiency of green light in the second sub-pixel 22, and increase the light extraction efficiency of blue light in the third sub-pixel 23.

The anode electrode 4 is disposed on the reflective electrode 42. The anode electrode 4 is formed to supply holes to the common light-emitting layer 5. The anode electrode 4 may be provided transparently so that light reflected from the reflective electrode 42 may travel upward. The anode electrode 4 may be formed of a transparent material, but is not limited thereto, and may be formed in the form of a thin film with a thin metal material. For example, the anode electrode 4 may include titanium nitride (TiN), but is not limited thereto. The anode electrode 4 may be formed of a very thin film so that the light reflected from the reflective electrode 42 may travel upward. For example, a thickness of the anode electrode 4 may be about 5 nm or less. For example, the thickness of the anode electrode 4 may be about 3 nm or less, but is not limited thereto.

The anode electrode 4 may be electrically connected to each of the first to third transistors 31, 32, and 33 through the contact holes CNT1 to CNT6 so that a driving voltage provided by each of the first to third transistors 31, 32, and 33 may be applied to the anode electrode 4. The anode electrode 4 may supply holes to the common light-emitting layer 5 when the driving voltages are applied from the first to third transistors 31, 32, and 33.

The anode electrodes 4a, 4b, and 4c disposed in the sub-pixels 21, 22, and 23, respectively, may be disposed on different layers in the light-emitting areas EA1, EA2, and EA3.

The bank BK may be disposed on the anode electrode 4 (4a, 4b, and 4c). The bank BK may be formed of an inorganic material, such as silicon nitride (SiNx), silicon oxide (SiOx), aluminum oxide (Al2O3), etc., but the embodiments of the present specification are not limited thereto.

In the light-emitting areas EA1, EA2, and EA3, the bank BK may define the light-emitting areas EA1, EA2, and EA3 by exposing the upper surface of the anode electrode 4 (4a, 4b, and 4c). On the other hand, in the non-light-emitting areas NEA1, NEA2, and NEA3, the bank BK may cover the upper surfaces of the anode electrodes 4a, 4b, and 4c.

The common light-emitting layer 5 is formed on the anode electrode 4 and the bank BK. The common light-emitting layer 5 may also be formed on filling members 10 disposed between the plurality of sub-pixels 21, 22, and 23. The common light-emitting layer 5 may come into contact with the upper surface of the anode electrode 4. The common light-emitting layer 5 may come into direct contact with the side surfaces and upper surface of the bank BK.

An organic light-emitting diode OLED according to one embodiment may include the anode electrode 4, the cathode electrode 6, and the common light-emitting layer 5 between the anode electrode 4 and the cathode electrode 6.

The common light-emitting layer 5 may be provided to emit white (W) light. To this end, the common light-emitting layer 5 may include a plurality of stacks for emitting light of different colors. Specifically, the common light-emitting layer 5 may include a first stack, a second stack, and a charge generation layer CGL provided between the first stack and the second stack.

The cathode electrode 6 is formed on the common light-emitting layer 5. The cathode electrode 6 may serve as a cathode of the display apparatus 1. Like the common light-emitting layer 5, the cathode electrode 6 is formed in each of the sub-pixels 21, 22, and 23 and between the sub-pixels 21, 22, and 23.

In the display apparatus 1 according to one embodiment, the cathode electrode 6 may be formed as a cathode electrode including a translucent material in order to implement white light with light efficiency in the top emission type. Accordingly, the microcavity effect can be obtained for each of the first to third sub-pixels 21, 22, and 23. When the cathode electrode 6 is formed as the cathode electrode including a translucent material, the microcavity effect can be obtained as light is reflected and re-reflected repeatedly between the cathode electrode 6 and the reflective electrode 42, thereby increasing light extraction efficiency.

Meanwhile, since the cathode electrode 6 is formed on the upper surface of the common light-emitting layer 5, the cathode electrode 6 may be formed along a profile of the common light-emitting layer 5. Since the common light-emitting layer 5 is formed along the profile of the anode electrode 4 in the light-emitting area, the cathode electrode 6 may be eventually formed along the profile of the anode electrode 4. In addition, the capping layer 7 on the cathode electrode 6 may also be formed along a profile of the cathode electrode 6.

The capping layer 7 may be formed of an inorganic insulation material, but is not limited thereto. The capping layer 7 may be formed of a single layer, but is not limited thereto, and may be formed of multiple layers. The capping layer 7 may be disposed on the cathode electrode 6 to protect the organic light-emitting diode OLED.

The encapsulation layer 8 is formed on the cathode electrode 6 to prevent or at least reduce external moisture from penetrating the common light-emitting layer 5. The encapsulation layer 8 may be formed of an inorganic insulation material or formed in a structure in which an inorganic insulation material and an organic insulation material are alternately stacked, but is not necessarily limited thereto.

The color filter layer 9 is formed on the encapsulation layer 8. The color filter layer 9 may include the red (R) first color filter 91 provided in the first sub-pixel 21, the green (G) second color filter 92 provided in the second sub-pixel 22, and the blue (B) third color filter 93 provided in the third sub-pixel 23, but is not necessarily limited thereto.

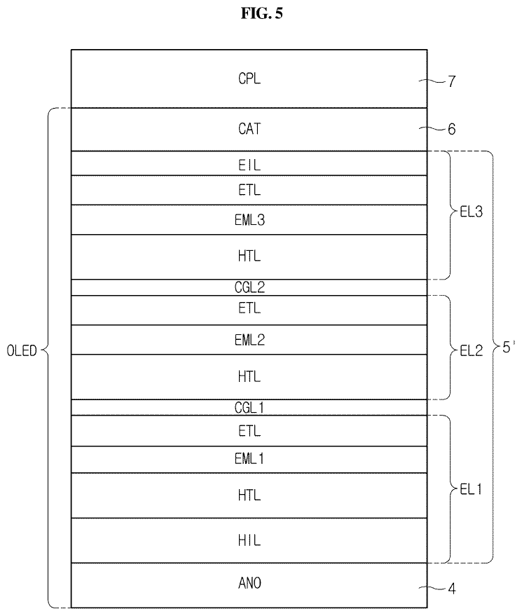

FIG. 4 is a cross-sectional view of an organic light emitting diode OLED according to FIG. 2 according to one embodiment. FIG. 5 is a cross-sectional view of an organic light-emitting diode OLED according to a modified example of FIG. 2 according to one embodiment.

Referring to FIGS. 2 to 5, the common light-emitting layer 5 may include the first stack EL1, the second stack EL2, and the first charge generation layer CGL1, which are provided on the anode electrode 4.

The first stack EL1 may be provided on the anode electrode 4 and configured in a structure in which a hole injecting layer HIL, a hole transporting layer HTL, a blue (B) light-emitting layer EML1, and an electron transporting layer ETL may be sequentially stacked.

The first stack EL1 may be disposed between the first sub-pixel 21 and the second sub-pixel 22 and between the second sub-pixel 22 and the third sub-pixel 23.

The first charge generation layer CGL1 serves to supply charges to the first stack EL1 and the second stack EL2. The first charge generation layer CGL1 may include an N-type charge generation layer for supplying electrons to the first stack EL1 and a P-type charge generation layer for supplying holes to the second stack EL2. The N-type charge generation layer may include a metallic material as a dopant.

The second stack EL2 may be provided on the first stack EL1 and configured in a structure in which a hole transporting layer HTL, a yellow-green (YG) light-emitting layer EML2, an electron transporting layer ETL, and an electron injecting layer EIL are sequentially stacked.

The second stack EL2 may be disposed between the first sub-pixel 21 and the second sub-pixel 22 and between the second sub-pixel 22 and the third sub-pixel 23.

As a result, the common light-emitting layer 5 may be provided as a common layer across the first to third sub-pixels 21, 22, and 23 as illustrated in FIG. 2.

As illustrated in FIG. 5, a common light-emitting layer 5′ of the organic light-emitting diode OLED according to one embodiment may include the first stack EL1 provided on the anode electrode 4, the second stack EL2, a third stack EL3, the first charge generation layer CGL1 between the first stack EL1 and the second stack EL2, and a second charge generation layer CGL2 between the second stack EL2 and the third stack EL3.

The first stack EL1 may be provided on the anode electrode 4 and configured in a structure in which a hole injecting layer HIL, a hole transporting layer HTL, a blue (B) light-emitting layer EML1, and an electron transporting layer ETL may be sequentially stacked.

The first stack EL1 may be disposed between the first sub-pixel 21 and the second sub-pixel 22 and between the second sub-pixel 22 and the third sub-pixel 23, that is, on the bank BK.

The first charge generation layer CGL1 serves to supply charges to the first stack EL1 and the second stack EL2. The first charge generation layer CGL1 may include an N-type charge generation layer for supplying electrons to the first stack EL1 and a P-type charge generation layer for supplying holes to the second stack EL2. The N-type charge generation layer may include a metallic material as a dopant.

The second stack EL2 may be provided on the first stack EL1 and configured in a structure in which a hole transporting layer HTL, a green (G) light-emitting layer EML2, and an electron transporting layer ETL are sequentially stacked.

The second stack EL2 may be disposed between the first sub-pixel 21 and the second sub-pixel 22 and disposed between the second sub-pixel 22 and the third sub-pixel 23, that is, on the bank BK.

The second charge generation layer CGL2 serves to supply charges to the second stack EL2 and the third stack EL3. The second charge generation layer CGL2 may include an N-type charge generation layer for supplying electrons to the second stack EL2 and a P-type charge generation layer for supplying holes to the third stack EL3. The N-type charge generation layer may include a metallic material as a dopant.

The third stack EL3 may be provided on the second stack EL2 and configured in a structure in which a hole transporting layer HTL, a red (R) light-emitting layer EML3, an electron transporting layer ETL, and an electron injecting layer EIL are sequentially stacked.

Hereinafter, a method of manufacturing the display apparatus 1 according to one embodiment will be described. While describing the method of manufacturing the display apparatus 1 according to one embodiment, the descriptions of parts already described in FIGS. 1 to 5 will be briefly given or omitted.

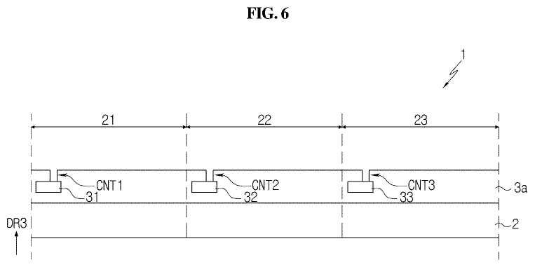

FIGS. 6 to 15 are cross-sectional views for each process of a method of manufacturing a display apparatus according to one embodiment.

First, referring to FIG. 6, the substrate 2 having the first insulating layer 3a disposed thereon is provided. The first insulating layer 3a may define the first to third contact holes CNT1, CNT2, and CNT3 exposing the transistors 31, 32, and 33. Circuit elements including the plurality of thin film transistors 31, 32, and 33, various signal lines, capacitors, and the like may be provided in the first insulating layer 3a of each sub-pixel 21, 22, or 23.

The first insulating layer 3a may be disposed on the entire area of the substrate 2, but is not limited thereto.

The first to third contact holes CNT1, CNT2, and CNT3 may be provided in an empty state, but are not limited thereto, and the connection electrode may be disposed in each of the first to third contact holes CNT1, CNT2, and CNT3.

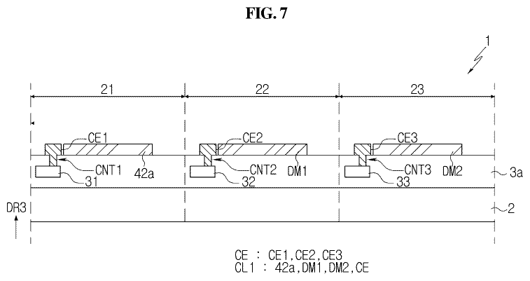

Subsequently, referring to FIG. 7, the first conductive layer CL1 may be patterned and disposed on the first insulating layer 3a.

The first conductive layer CL1 before being patterned may be disposed on the first insulating layer 3a and disposed across the entire area of the first insulating layer 3a. A patterned first photoresist (not illustrated) may be disposed on the first conductive layer CL1, and a part of the first conductive layer CL1 exposed by the first photoresist (not illustrated) may be removed, and the first conductive layer CL1 may be patterned to form the first reflective electrode 42a, the first dummy electrode DM1, the second dummy electrode DM2, and the connection electrode CE (CE1, CE2, and CE3). The first photoresist (not illustrated) may be removed by an ashing process.

The first reflective electrode 42a, the first dummy electrode DM1, the second dummy electrode DM2, and the connection electrode CE (CE1, CE2, and CE3) may be patterned and separated, but are not limited thereto.

The connection electrodes CE1, CE2, and CE3 may fill the first to third contact holes CNT1, CNT2, and CNT3 and come into contact with the transistors 31, 32, and 33, respectively.

The first reflective electrode 42a, the first dummy electrode DM1, the second dummy electrode DM2, and the connection electrode CE (CE1, CE2, and CE3) may be formed through the same process (or mask) and may include the same material. The first reflective electrode 42a may be disposed in the first sub-pixel 21, the first dummy electrode DM1 may be disposed in the second sub-pixel 22, and the second dummy electrode DM2 may be disposed in the third sub-pixel 23.

Since the first reflective electrode 42a, the first dummy electrode DM1, and the second dummy electrode DM2 are disposed, it is possible to suppress or prevent over-etching of the first insulating layer 3a, which may occur during the process of patterning the first conductive layer CL1. Accordingly, it is possible to minimize or at least reduce a thickness deviation of the first insulating layers 3a disposed in the sub-pixels 21, 22, and 23 and a thickness deviation of the first insulating layers 3a in each manufactured display apparatus 1. Accordingly, it is possible to further improve the reliability of the process of manufacturing the display apparatus 1 and more smoothly perform the manufacturing process, thereby minimizing or at least reducing the increase in the time and cost required for the process.

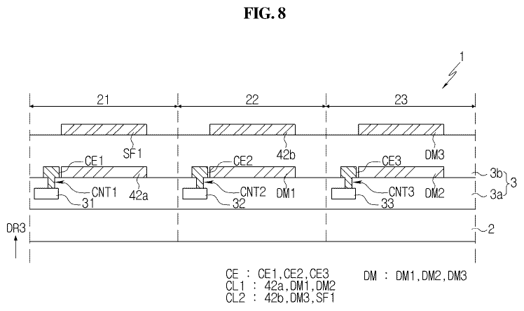

Subsequently, referring to FIG. 8, the second insulating layer 3b may be disposed on the first conductive layer CL1, and the second conductive layer CL2 may be patterned and disposed on the second insulating layer 3b.

The second insulating layer 3b may cover the first reflective electrode 42a, the first dummy electrode DM1, the second dummy electrode DM2, and the connection electrode CE (CE1, CE2, and CE3) and may be disposed across the entire area of the first insulating layer 3a.

The second conductive layer CL2 before being patterned may be disposed on the second insulating layer 3b and disposed across the entire area of the second insulating layer 3b. A patterned second photoresist (not illustrated) may be disposed on the second conductive layer CL2, and a part of the second conductive layer CL2 exposed by the second photoresist (not illustrated) may be removed, and the second conductive layer CL2 may be patterned to form a first sacrificial layer SF1, the second reflective electrode 42b, and the third dummy electrode DM3. The second photoresist (not illustrated) may be removed by an ashing process.

The first sacrificial layer SF1, the second reflective electrode 42b, and the third dummy electrode DM3 may be patterned and separated, but are not limited thereto.

The first sacrificial layer SF1, the second reflective electrode 42b, and the third dummy electrode DM3 may be formed through the same process (or mask) and may include the same material. The first sacrificial layer SF1 may be disposed in the first sub-pixel 21, the second reflective electrode 42b may be disposed in the second sub-pixel 22, and the third dummy electrode DM3 may be disposed in the third sub-pixel 23.

As the first sacrificial layer SF1, the second reflective electrode 42b, and the third dummy electrode DM3 are disposed, it is possible to suppress or prevent over-etching of the second insulating layer 3b, which may occur during the process of patterning the second conductive layer CL2. Accordingly, it is possible to minimize or at least reduce a thickness deviation of the second insulating layers 3b disposed in the sub-pixels 21, 22, and 23 and a thickness deviation of the second insulating layers 3b in each manufactured display apparatus 1. Accordingly, it is possible to further improve the reliability of the process of manufacturing the display apparatus 1 and more smoothly perform the manufacturing process, thereby minimizing or at least reducing the increase in the time and cost required for the process.

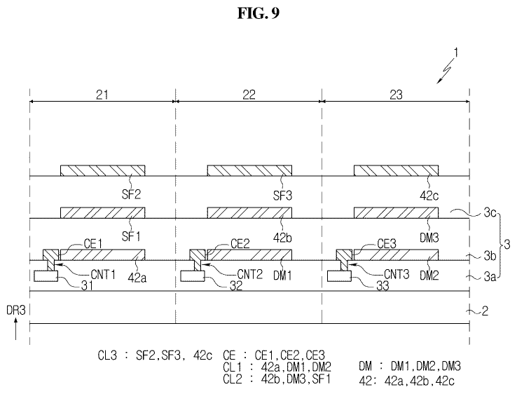

Subsequently, referring to FIG. 9, the third insulating layer 3c may be disposed on the second conductive layer CL2, and the third conductive layer CL3 may be patterned and disposed on the third insulating layer 3c.

The third insulating layer 3c may cover the first sacrificial layer SF1, the second reflective electrode 42b, and the third dummy electrode DM3 and may be disposed across the entire area of the second insulating layer 3b.

The third conductive layer CL3 before being patterned may be disposed on the third insulating layer 3c and disposed across the entire area of the third insulating layer 3c. A patterned third photoresist (not illustrated) may be disposed on the third conductive layer CL3, and a part of the third conductive layer CL3 exposed by the third photoresist (not illustrated) may be removed, and the third conductive layer CL3 may be patterned to form a second sacrificial layer SF2, a third sacrificial layer SF3, and the third reflective layer 42c. The third photoresist (not illustrated) may be removed by an ashing process.

The second sacrificial layer SF2, the third sacrificial layer SF3, and the third reflective electrode 42c may be patterned and separated, but are not limited thereto.

The second sacrificial layer SF2, the third sacrificial layer SF3, and the third reflective electrode 42c may be formed through the same process (or mask) and may include the same material. The second sacrificial layer SF2 may be disposed in the first sub-pixel 21, the third sacrificial layer SF3 may be disposed in the second sub-pixel 22, and the third reflective layer 42c may be disposed in the third sub-pixel 23.

As the second sacrificial layer SF2, the third sacrificial layer SF3, and the third reflective electrode 42c are disposed, it is possible to suppress or prevent over etching of the third insulating layer 3c, which may occur during the process of patterning the third conductive layer CL3. Accordingly, it is possible to minimize or at least reduce a thickness deviation of the third insulating layers 3c disposed in the sub-pixels 21, 22, and 23 and a thickness deviation of the third insulating layers 3c in each manufactured display apparatus 1. Accordingly, it is possible to further improve the reliability of the process of manufacturing the display apparatus 1 and more smoothly perform the manufacturing process, thereby minimizing or at least reducing the increase in the time and cost required for the process.

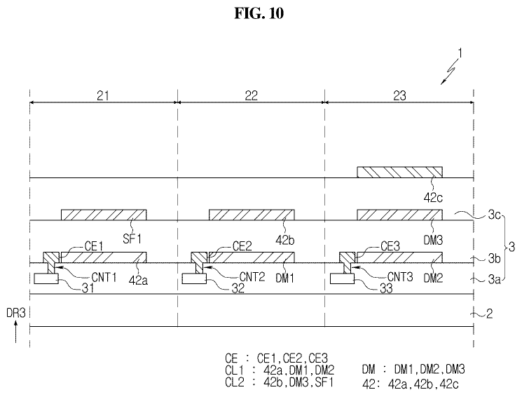

Subsequently, referring to FIG. 10, the second sacrificial layer SF2 and the third sacrificial layer SF3 are removed. The second sacrificial layer SF2 and the third sacrificial layer SF3 may be removed by wet etching.

Accordingly, by removing the second sacrificial layer SF2 overlapping the first reflective electrode 42a and the third sacrificial layer SF3 overlapping the second reflective electrode 42b, it is possible to satisfy the microcavity in the first sub-pixel 21 and the second sub-pixel 22 and minimize the over-etching of the third insulating layer 3c, thereby minimizing or at least reducing a thickness deviation of the third insulating layer 3c.

However, the etching method of the second sacrificial layer SF2 and the third sacrificial layer SF3 is not limited to the wet etching. For example, when the second sacrificial layer SF2 and the third sacrificial layer SF3 have a sufficient selectivity with the third insulating layer 3c and the etching of the third insulating layer 3c is limited during the etching of the second sacrificial layer SF2 and the third sacrificial layer SF3, the second sacrificial layer SF2 and the third sacrificial layer SF3 may also be etched by dry etching, etc.

A patterned fourth photoresist (not illustrated) may be disposed on the third reflective electrode 42c, the second sacrificial layer SF2 and the third sacrificial layer SF3 exposed by the fourth photoresist (not illustrated) may be removed by wet etching, and the third reflective electrode 42c may remain. The fourth photoresist (not illustrated) may be removed by an ashing process.

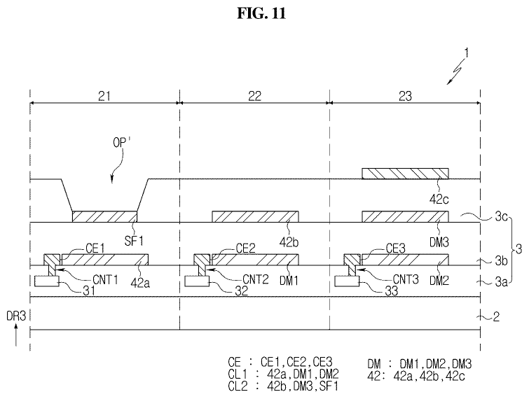

Subsequently, referring to FIG. 11, an opening OP′ exposing the first sacrificial layer SF1 is formed.

A patterned fifth photoresist (not illustrated) may be placed on the third insulating layer 3c, and the third insulating layer 3c exposed by the fifth photoresist (not illustrated) may be etched by dry etching. Accordingly, the opening OP′ defined by the third insulating layer 3c may be formed, and the opening OP′ may expose the first sacrificial layer SF1.

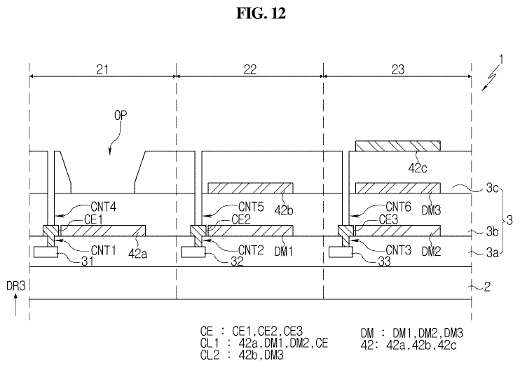

Subsequently, referring to FIG. 12, the first sacrificial layer SF1 exposed by the opening OP is removed by wet etching to form the fourth to sixth contact holes CNT4 to CNT6.

A patterned sixth photoresist (not illustrated) may be disposed on the third insulating layer 3c, and the first sacrificial layer SF1 exposed by the sixth photoresist (not illustrated) may be etched by wet etching. Accordingly, the opening OP defined by the third insulating layer 3c may be formed, and the opening OP may expose the second insulating layer 3b.

However, the etching method of the first sacrificial layer SF is not limited to the wet etching. For example, when the first sacrificial layer SF1 has a sufficient selectivity with the second insulating layer 3b and the etching of the second insulating layer 3b is limited during the etching process of the first sacrificial layer SF1, the first sacrificial layer SF1 may also be etched by dry etching, etc.

Subsequently, the fourth to sixth contact holes CNT4 to CNT6 may be formed in the non-light-emitting areas NEA1, NEA2, and NEA3, respectively. Each of the fourth to sixth contact holes CNT4 to CNT6 may pass through the third insulating layer 3c and the second insulating layer 3b in the thickness direction (the third direction DR3) to expose the transistors 31, 32, and 33.

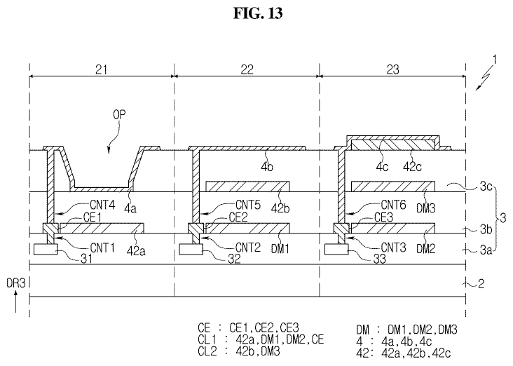

Subsequently, referring to FIG. 13, the anode electrodes 4a, 4b, and 4c may be disposed on the third insulating layer 3c and the second insulating layer 3b.

The anode electrode 4 before being patterned may be disposed on the third insulating layer 3c and the second insulating layer 3b with at least a part thereof disposed in the opening OP and disposed across the entire area of the third insulating layer 3c. A patterned seventh photoresist (not illustrated) may be disposed on the anode electrode 4, a part of the anode electrode 4 exposed by the seventh photoresist (not illustrated) may be removed, and the anode electrode 4 may be patterned to form the anode electrodes 4a, 4b, and 4c. The seventh photoresist (not illustrated) may be removed by an ashing process.

The anode electrodes 4a, 4b, and 4c may be separately patterned, but are not limited thereto.

The anode electrodes 4a, 4b, and 4c may be formed through the same process (or mask) and may include the same material. The first anode electrode 4a may be disposed in the first sub-pixel 21, the second anode electrode 4b may be disposed in the second sub-pixel 22, and the third anode electrode 4c may be disposed in the third sub-pixel 23.

The anode electrodes 4a, 4b, and 4c may fill the fourth to sixth contact holes CNT4, CNT5, and CNT6 and come into contact with the connection electrodes CE1, CE2, and CE3, respectively.

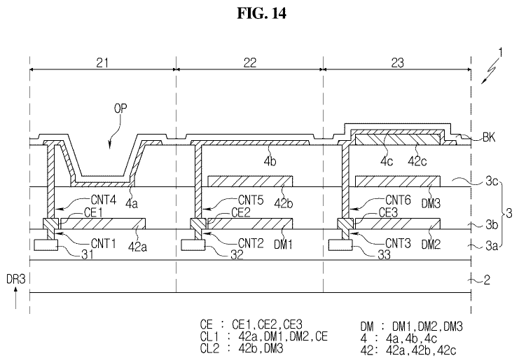

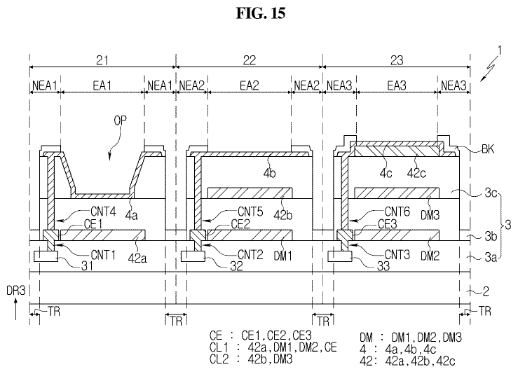

Subsequently, referring to FIGS. 14 and 15, the bank BK may be patterned and disposed on the anode electrodes 4a, 4b, and 4c, and the trench TR may be formed.

The bank BK before being patterned may be disposed on the third insulating layer 3c and the anode electrodes 4a, 4b, and 4c, and at least a part thereof may be disposed in the opening OP and disposed across the entire area of the third insulating layer 3c. A patterned eighth photoresist (not illustrated) may be disposed on the bank BK, and a part of the bank BK exposed by the eighth photoresist (not illustrated) may be removed to expose the anode electrodes 4a, 4b, and 4c. Accordingly, the light-emitting areas EA1, EA2, and EA3 and the non-light-emitting areas NEA1, NEA2, and NEA3 may be formed. The eighth photoresist (not illustrated) may be removed by an ashing process.

Referring further to FIG. 2, the common light-emitting layer 5, the cathode electrode 6, the capping layer 7, the encapsulation layer 8, and the color filter layer 9 may be further disposed sequentially on the bank BK.

Hereinafter, other embodiments of the present specification will be described. For contents substantially the same as those described with reference to FIGS. 1 to 15 among components included in other embodiments, the same reference numerals are given, and the overlapping contents may be omitted or briefly described.

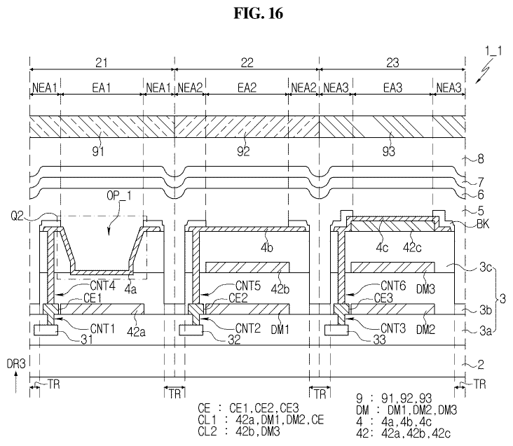

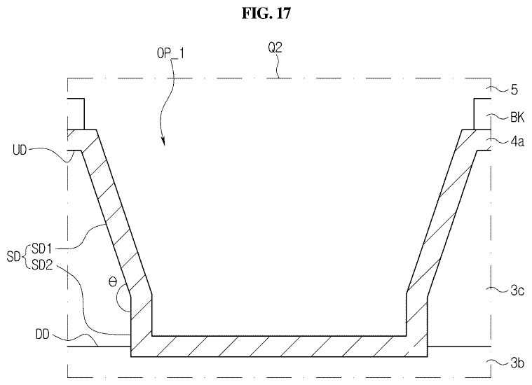

FIG. 16 is a cross-sectional view of a display apparatus according to another embodiment. FIG. 17 is an enlarged view of area Q2 in FIG. 16 according to one embodiment.

Referring to FIGS. 16 and 17, in a display apparatus 1_1 according to the present embodiment, the upper surface of the second insulating layer 3b may have a step difference in the first light-emitting area EA1.

During the etching process of the first sacrificial layer SF1 (see FIG. 11), the second insulating layer 3b may be over-etched. Accordingly, an area covered by the first sacrificial layer SF1 (see FIG. 11) of the second insulating layer 3b may have a step difference from the remaining area.

The second sidewall SD2 of an opening OP_1 may be formed of the third insulating layer 3c and the second insulating layer 3b.

The third insulating layer 3c and the second insulating layer 3b forming the second sidewall SD2 may have different slopes in a cross-sectional view, but are not limited thereto.

Even in this case, the lower insulating layers 3a, 3b, and 3c may be suppressed or prevented from being over-etched by the reflective electrode 42, the dummy electrode DM, and the first to third sacrificial layers SF1, SF2, and SF3 (see FIG. 9). Accordingly, it is possible to minimize the thickness deviation of the insulating layers 3a, 3b, and 3c and the deviation of the microcavity of the sub-pixels 21, 22, and 23, enable the high-color reproduction of the display apparatus 1_1, and reduce power consumption.

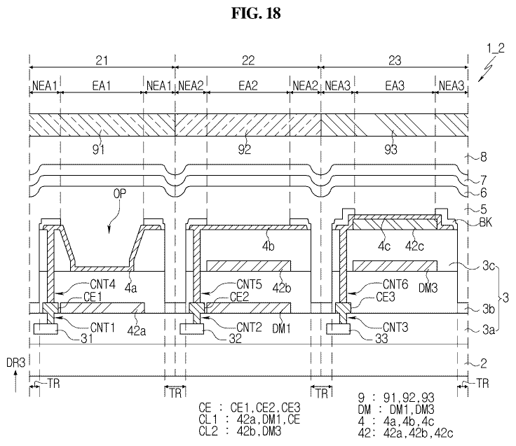

FIG. 18 is a cross-sectional view of a display apparatus according to still another embodiment.

Referring to FIG. 18, a display apparatus 1_2 according to the present embodiment may omit at least one of the dummy electrodes DM of FIG. 2.

For example, the second dummy electrode DM2 (see FIG. 2) disposed in the third sub-pixel 23 of FIG. 2 may be omitted. In this case, the first sub-pixel 21 may include the first reflective electrode 42a, the second sub-pixel 22 may include the first dummy electrode DM1 and the second reflective electrode 42b, and the third sub-pixel 23 may include the third dummy electrode DM3 and the third reflective electrode 42c.

However, the embodiments of the present specification are not limited thereto, and the first dummy electrode DM1 may be omitted, or the third dummy electrode DM3 may be omitted.

Since the second dummy electrode DM2 (see FIG. 2) disposed under the third reflective electrode 42c is omitted, the second insulating layer 3b and the third insulating layer 3c may be further planarized, thereby improving the uniformity of the third reflective electrode 42c.

The present embodiment has described that one of the first dummy electrode DM1, the second dummy electrode DM2 (see FIG. 2), and the third dummy electrode DM3 of the embodiment of FIG. 2 is omitted, but the embodiments of the present specification are not limited thereto. For example, two dummy electrodes selected from the first to third dummy electrodes DM1, DM2, and DM3 of the embodiment of FIG. 2 may be omitted, or all of the dummy electrodes DM1, DM2, and DM3 may be omitted.

Even in this case, the lower insulating layers 3a, 3b, and 3c may be suppressed or prevented from being over-etched by the reflective electrode 42, the dummy electrode DM, and the first to third sacrificial layers SF1, SF2, and SF3 (see FIG. 9). Accordingly, it is possible to minimize or at least reduce the thickness deviation of the insulating layers 3a, 3b, and 3c and the deviation of the microcavity of the sub-pixels 21, 22, and 23, enable the high-color reproduction of the display apparatus 1_2, and reduce power consumption.

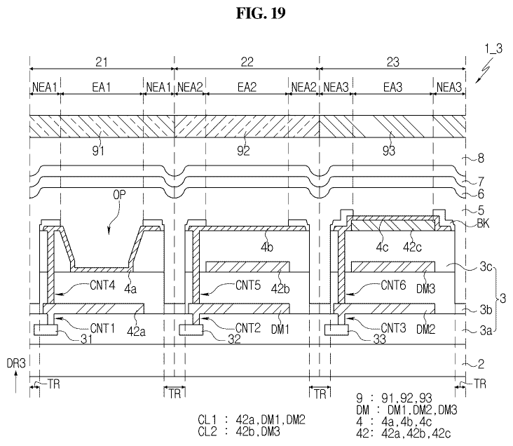

FIG. 19 is a cross-sectional view of a display apparatus according to yet another embodiment.

Referring to FIG. 19, a display apparatus 1_3 according to the present embodiment may include the first conductive layer CL1, and the transistors 31, 32, and 33 and the anode electrodes 4a, 4b, and 4c may be electrically connected through the first conductive layer CL1.

Specifically, the first conductive layer CL1 may include the first reflective electrode 42a, the first dummy electrode DM1, and the second dummy electrode DM2.

The first reflective electrode 42a, the first dummy electrode DM1, and the second dummy electrode DM2 may fill the first to third contact holes CNT1, CNT2, and CNT3 and come into contact with the transistors 31, 32, and 33, respectively.

The fourth to sixth contact holes CNT4, CNT5, and CNT6 may expose the first reflective electrode 42a, the first dummy electrode DM1, and the second dummy electrode DM2, respectively.

The anode electrodes 4a, 4b, and 4c may fill the fourth to sixth contact holes CNT4, CNT5, and CNT6 and come into contact with the first reflective electrode 42a, the first dummy electrode DM1, and the second dummy electrode DM2.

In this case, since the separate connection electrode CE (see FIG. 2) is omitted, it is possible to further facilitate the manufacturing process of patterning the first conductive layer CL1.

Even in this case, the lower insulating layers 3a, 3b, and 3c may be suppressed or prevented from being over-etched by the reflective electrode 42, the dummy electrode DM, and the first to third sacrificial layers SF1, SF2, and SF3 (see FIG. 9). Accordingly, it is possible to minimize or at least reduce the thickness deviation of the insulating layers 3a, 3b, and 3c and the deviation of the microcavity of the sub-pixels 21, 22, and 23, enable the high-color reproduction of the display apparatus 1_3, and reduce power consumption.

A display apparatus according to various embodiments of the present specification may be described as follows.

A display apparatus according to embodiments of the present specification includes a substrate having a first sub-pixel, a second sub-pixel, and a third sub-pixel, each of which includes a light-emitting area and a non-light-emitting area, a first insulating layer disposed on the substrate, a first conductive layer disposed on the first insulating layer and including a first reflective electrode of the first sub-pixel, a first dummy electrode of the second sub-pixel, and a second dummy electrode of the third sub-pixel, a second insulating layer disposed on the first conductive layer, a second conductive layer disposed on the second insulating layer and including a second reflective electrode of the second sub-pixel and a third dummy electrode of the third sub-pixel, a third insulating layer disposed on the second conductive layer, and a third reflective electrode of the third sub-pixel disposed on the third insulating layer.

According to various embodiments of the present specification, the display apparatus may further include anode electrodes of the sub-pixels disposed on at least one of the second insulating layer and the third insulating layer, in which surface heights of the anode electrodes in light-emitting areas of the sub-pixels may be different.

According to various embodiments of the present specification, the anode electrode of the first sub-pixel may be disposed on the second insulating layer, the anode electrode of the second sub-pixel may be disposed on the third insulating layer, and the anode electrode of the third sub-pixel may be disposed on the third reflective electrode.

According to various embodiments of the present specification, in the first sub-pixel, the third insulating layer may include an opening, and the anode electrode of the first sub-pixel may be disposed in the opening.

According to various embodiments of the present specification, the anode electrode may come into direct contact with an upper surface of the second insulating layer in the opening.

According to various embodiments of the present specification, in the second sub-pixel, the anode electrode may be disposed directly on an upper surface of the third insulating layer.

According to various embodiments of the present specification, in the third sub-pixel, the anode electrode may be disposed directly on an upper surface of the third reflective electrode.

According to various embodiments of the present specification, in the opening, a slope of a first sidewall and a slope of a second sidewall of the third insulating layer may be different, and the second sidewall may be connected to the first sidewall and a lower surface of the third insulating layer.

According to various embodiments of the present specification, the display apparatus may further include a bank disposed on the anode electrode in the non-light-emitting area of each sub-pixel.

According to various embodiments of the present specification, the display apparatus may further include a common light-emitting layer disposed on the anode electrode and the bank of each sub-pixel.

According to various embodiments of the present specification, the first insulating layer and the second insulating layer may include the same material.

According to various embodiments of the present specification, the display apparatus may further include transistors in the first insulating layer of each sub-pixel.

According to various embodiments of the present specification, the display apparatus may further include a trench formed in the second insulating layer and the third insulating layer in the non-light-emitting area.

According to various embodiments of the present specification, the first reflective electrode of the first sub-pixel, the first dummy electrode of the second sub-pixel, and the second dummy electrode of the third sub-pixel may include the same material.

According to various embodiments of the present specification, the second reflective electrode of the second sub-pixel and the third dummy electrode of the third sub-pixel may include the same material.

According to various embodiments of the present specification, there is provided a display apparatus including a substrate having a first sub-pixel, a second sub-pixel, and a third sub-pixel, each of which includes a light-emitting area and a non-light-emitting area, a first insulating layer on the substrate, a first reflective electrode of the first sub-pixel on the first insulating layer, a second insulating layer on the first reflective electrode, a second reflective electrode of the second sub-pixel on the second insulating layer, a third insulating layer on the second reflective electrode, a third reflective electrode of the third sub-pixel on the third insulating layer, and anode electrodes of the sub-pixels on the second insulating layer or the third insulating layer, in which, in the light-emitting area, surface heights of the anode electrodes of the sub-pixels are different.

According to various embodiments of the present specification, a surface height of the anode electrode disposed in the light-emitting area of the third sub-pixel may be greater than a surface height of the anode electrode disposed in the light-emitting area of the second sub-pixel.

According to various embodiments of the present specification, the surface height of the anode electrode disposed in the light-emitting area of the second sub-pixel may be greater than a surface height of the anode electrode disposed in the light-emitting area of the first sub-pixel.

Although the embodiments have been described above with reference to the accompanying drawings, those skilled in the art to which the present specification pertains will be able to understand that the above-described technical configuration can be carried out in other specific forms without changing the technical idea or essential features thereof. Accordingly, it may be understood that the above-described embodiments are illustrative and not restrictive in all respects. In addition, the scope of the embodiments is determined by the appended claims rather than detailed description. In addition, the meaning and scope of the claims and all changed or modified forms derived from the equivalent concept thereof may be construed as being included in the scope of the embodiments.

### DESCRIPTION OF REFERENCE NUMERALS

1: display apparatus
2: substrate
3: insulating layer
4: anode electrode
5: common light-emitting layer
6: cathode electrode
7: capping layer
8: encapsulation layer
9: color filter layer
42: reflective layer
DM: dummy electrode
TR: trench

What is claimed is:

1. A display apparatus comprising:
a substrate having a first sub-pixel, a second sub-pixel, and a third sub-pixel, each of the first sub-pixel, the second sub-pixel, and the third sub-pixel including a light-emitting area and a non-light-emitting area;
a first insulating layer on the substrate;
a first conductive layer on the first insulating layer, the first conductive layer including a first reflective electrode of the first sub-pixel, a first dummy electrode of the second sub-pixel, and a second dummy electrode of the third sub-pixel;
a second insulating layer on the first conductive layer;
a second conductive layer on the second insulating layer, the second conductive layer including a second reflective electrode of the second sub-pixel and a third dummy electrode of the third sub-pixel;
a third insulating layer on the second conductive layer; and
a third reflective electrode of the third sub-pixel disposed on the third insulating layer.

2. The display apparatus of claim 1, further comprising:
anode electrodes of the first sub-pixel, the second sub-pixel, and the third sub-pixel on at least one of the second insulating layer and the third insulating layer,
wherein surface heights of the anode electrodes in light-emitting areas of the first sub-pixel, the second sub-pixel, and the third sub-pixel are different.

3. The display apparatus of claim 2, wherein the anode electrode of the first sub-pixel is on the second insulating layer, the anode electrode of the second sub-pixel is on the third insulating layer, and the anode electrode of the third sub-pixel is on the third reflective electrode.

4. The display apparatus of claim 2, wherein, in the first sub-pixel, the third insulating layer includes an opening and the anode electrode of the first sub-pixel is in the opening.

5. The display apparatus of claim 4, wherein the anode electrode of the first sub-pixel is in direct contact with an upper surface of the second insulating layer in the opening.

6. The display apparatus of claim 5, wherein, in the second sub-pixel, the anode electrode is directly on an upper surface of the third insulating layer.

7. The display apparatus of claim 6, wherein, in the third sub-pixel, the anode electrode is directly on an upper surface of the third reflective electrode.

8. The display apparatus of claim 4, wherein the third insulating layer includes an upper surface, a lower surface that is opposite to the upper surface, a first sidewall, and a second sidewall,
in the opening, the first sidewall extends from the upper surface and is connected to the second sidewall, and the second sidewall extends from the first sidewall and is connected to the lower surface of the third insulating layer, and
a slope of the first sidewall is different from a slope of the second sidewall.

9. The display apparatus of claim 2, further comprising:
a bank on the anode electrode in the non-light-emitting area of each of the first sub-pixel, the second sub-pixel, and the third sub-pixel.

10. The display apparatus of claim 9, further comprising:
a common light-emitting layer on the anode electrode and the bank of each of the first sub-pixel, the second sub-pixel, and the third sub-pixel.

11. The display apparatus of claim 1, wherein the first insulating layer and the second insulating layer include a same material.

12. The display apparatus of claim 1, further comprising:
transistors in the first insulating layer of each of the first sub-pixel, the second sub-pixel, and the third sub-pixel.

13. The display apparatus of claim 1, further comprising:
a trench in the second insulating layer and the third insulating layer in the non-light-emitting area.

14. The display apparatus of claim 1, wherein the first reflective electrode of the first sub-pixel, the first dummy electrode of the second sub-pixel, and the second dummy electrode of the third sub-pixel include a same material.

15. The display apparatus of claim 1, wherein the second reflective electrode of the second sub-pixel and the third dummy electrode of the third sub-pixel include a same material.

16. A display apparatus comprising:
a substrate having a first sub-pixel, a second sub-pixel, and a third sub-pixel, each of the first sub-pixel, the second sub-pixel, and the third sub-pixel including a light-emitting area and a non-light-emitting area;
a first insulating layer on the substrate;
a first reflective electrode of the first sub-pixel on the first insulating layer;
a second insulating layer on the first reflective electrode;
a second reflective electrode of the second sub-pixel on the second insulating layer;
a third insulating layer on the second reflective electrode;
a third reflective electrode of the third sub-pixel on the third insulating layer, and
anode electrodes of the first sub-pixel, the second sub-pixel, and the third sub-pixel on the second insulating layer or the third insulating layer,
wherein, in the light-emitting area, surface heights of the anode electrodes of the first sub-pixel, the second sub-pixel, and the third sub-pixel are different.

17. The display apparatus of claim 16, wherein a surface height of the anode electrode in the light-emitting area of the third sub-pixel is greater than a surface height of the anode electrode in the light-emitting area of the second sub-pixel.

18. The display apparatus of claim 17, wherein the surface height of the anode electrode in the light-emitting area of the second sub-pixel is greater than a surface height of the anode electrode disposed in the light-emitting area of the first sub-pixel.
